(19) United States
(12) Patent Application Publication
(10) Pub. No.: US 2015/0325718 A1
(43) Pub. Date: Nov. 12, 2015

(54) RAPID THERMAL PROCESSING OF BACK CONTACTS FOR CDTE SOLAR CELLS

(71) Applicant: Colorado School of Mines, Golden, CO (US)

(72) Inventors: Colin A. Wolden, Denver, CO (US); Joseph Beach, Aurora, CO (US); Timothy Ohno, Golden, CO (US)

(21) Appl. No.: 14/706,814

(22) Filed: May 7, 2015

Related U.S. Application Data
(60) Provisional application No. 61/989,772, filed on May 7, 2014.

(51) Int. Cl. H01L 31/0224; H01L 31/0296; H01L 31/18

(52) U.S. Cl. CPC H01L 31/022441; H01L 31/1828; H01L 31/1864; H01L 31/0296

(57) ABSTRACT

The present invention relates to a back contact and methods of making the same. In the present invention, rapid thermal processing is highly effective to activate ZnTe:Cu-based back contacts, and provides significant improvements in V_{OC}, FF, and efficiency.

### CROSS REFERENCE TO RELATED APPLICATIONS

This application claims priority and the benefit under 35 U.S.C. §119(e) to U.S. Provisional Patent Application Ser. No. 61/989,772 filed May 7, 2014, which is incorporated herein in its entirety by reference.

### GOVERNMENT LICENSE RIGHTS

This invention was made with government support under grant numbers DE-EE0004946 and AC36-08-GO28308 awarded by the Department of Energy (DOE). The Government has certain rights in the invention.

### BACKGROUND

CdTe solar cells on ultra-thin glass substrates are light and flexible. These traits can enable new applications that require high specific power, unique form factors, and low manufacturing costs. Flexible CdTe solar could be installed as building-integrated photovoltaics or in other configurations that are not amenable to rigid flat-panel installations. Flexible CdTe solar cells have been made in both superstrate and substrate configurations. Commercial CdTe modules are made in the superstrate configuration, which has higher efficiency to date. Substrate-configured cells were previously thought to be more amenable to high temperature roll-to-roll processing because they can be made on metal foils. Flexible superstrate cells have been made using DuPont clear Kapton® and flexible Corning® Willow® Glass. Flexible substrate cells have been made on metal foils. Efficiencies reaching 14% and 11.5% have been reported for flexible CdTe solar cells in a superstrate and substrate configuration, respectively.

A commonly used back contact for CdTe solar cells is comprised of a copper-doped zinc telluride buffer layer (ZnTe:Cu) followed by a metallization layer (i.e. Au, Ti, Cr, Ni, etc.). Back contacts can significantly limit CdTe solar cell performance, reducing both open circuit voltage (V_{OC}) and fill factor (FF). Copper is an essential component of effective back contacts, but its presence in the CdTe absorber creates detrimental recombination centers. In conventional processing, the contact is applied through vapor deposition techniques under conditions where the device is maintained at elevated temperatures (200-400° C.) for extended time (30-150 minutes).

A notorious challenge for CdTe solar cell technology is the formation of high quality ohmic back contacts. The large electron affinity of CdTe coupled with its inability to be highly doped leads to the formation of a Schottky barrier when contacted directly with a metal. Consequences of such barriers involve loss of V_{OC} and FF, which are often manifested by the presence of roll over behavior in current-density (J-V) curves. A common strategy to address this problem is through the insertion of a thin interfacial layer between the CdTe and metal contact. One such back buffer layer is CuₓTe (1<<2), which may be formed by the deposition of Cu followed by thermal treatments. Such contacts reduce the series resistance and have resulted in high efficiency devices, but copper migration to the front contact can lead to shunting and loss of efficiency. Another commonly used back buffer layer is copper doped zinc telluride (ZnTe:Cu), where the copper doping level is in the range of 1-5 wt %. ZnTe is chemically compatible with CdTe and offers a number of advantages. First, its valence band maximum is well aligned with that of CdTe, facilitating hole collection. With a band gap of the ˜2.2 eV. ZnTe also provides a back contact reflector for electrons which is proposed to reduce recombination at the back contact, particularly in thin or fully depleted device structures. Lastly, ZnTe can be highly doped (>1020 cm−3) to provide an effective tunnel junction to the metal layer. First Solar (Tempe Ariz.) recently revealed that it has integrated a ZnTe buffer into its current product line, crediting this layer for recent improvements in both champion cell efficiency and module reliability.

As most commonly practiced, ZnTe:Cu layers are deposited by sputtering at elevated temperature (240-360° C.) in processes whose duration are on the order of hours. The amount of copper is controlled by varying the composition of the sputter target or the layer thickness. It is well known that copper is a fast diffuser, with reported coefficients of ˜10-9 cm2/s at the temperatures employed. In addition to limiting throughput, another drawback of this procedure is that deposition and diffusion occur simultaneously, making process control difficult and resulting in copper migration throughout the device. In bulk CdTe a very small amount of copper may be beneficial; however, excessive amounts lead to deep level defects and recombination centers.

The present invention addresses these and other issues with contact manufacturing.

### SUMMARY OF THE INVENTION

The present invention relates to a high throughput approach for producing electrical back contacts to CdTe solar cells using rapid thermal processing (RTP) and the resulting CdTe solar cells. RTP is demonstrated as a highly effective approach for reducing back contact barriers in CdTe solar cells contacted with ZnTe:Cu buffer layers, substantially improving both FF (about 473%) and V_{OC} (4850 mV). Current density and quantum efficiency remain essentially unchanged, but a five-fold increase in minority carrier lifetime is observed which is attributed to passivation of recombination sites in the back contact region. Quantitative analysis of secondary ion mass spectrometry shows that the majority of Cu segregates to the Au metallization layer and that the ZnTe buffer appears to inhibit the Cu diffusion into CdTe. 3D imaging of the back contact region using atom probe tomography shows that optimized devices are characterized by preferential segregation of copper to both the Au:ZnTe and CdTe:ZnTe interfaces, perhaps in the form of CuₓTe. With its low thermal budget the RTP process has been successfully applied to multiple device architectures.

An aspect of the invention is a method to process a back contact for use with solar cells. A back contact is an electrode that may be used in solar cells to electrically connect the solar cells. In an embodiment of the present invention, the back contact may be deposited by evaporation at low temperature (in some embodiments, about 450° C.) and then annealed using rapid thermal processing (RTP) for less than about one minute. RTP offers a number of important advantages for this purpose. First, it is expected that high temperature-short time processes should be selective to Cu activation over diffusion based on energetics. The diffusion process is weakly activated, with reported activation energies of about 0.3-0.7 eV. In contrast, the enthalpies of formation for copper doping states range from about 1.5 to 2.5 eV. Second, RTP offers high throughput and precise control over time-temperature trajectories. Lastly, the low thermal budgets involved should not disturb the optimization of preceding processes used in front contact formation or absorber deposition, making this process easily adaptable to multiple device fabrication platforms.

The resulting devices exhibit significantly improved performance and reproducibility. As a result, the process offers a significant reduction in thermal budget over conventional techniques. The technique offers unique tools to control the redistribution of elements within the back contact, resulting in enhanced device efficiency through improvements in fill factor, open circuit voltage, and reproducibility. Thus, the efficacy and current density of the devices produced with the invention are also similar, if not improved, to contact backs produced by traditional methods.

An aspect of the invention is CdTe flexible cells. In an embodiment of the invention, the flexible CdTe superstrate cells are made on ultra-thin glass. The ultra-thin glass can reduce manufacturing costs and increase manufacturing throughput due to its lower thermal mass, which can reduce processing warm-up and cool-down times. It is also possible to produce CdTe solar cells on this glass in a roll-to-roll process. Lightweight, flexible solar has significant advantages over conventional technology for applications where specific power is important such as consumer electronics, transportation, remote installations, and military applications. The devices of the present invention take advantage of high specific power, flexible form factors, and lower installation and transportation costs. The efficiency of the devices produced by the present invention may be about 16.4% for a flexible CdTe solar cell. This increased efficacy is based on the quantum efficiency and capacitance-voltage measurements combined with device simulations. This efficiency is a marked improvement over the previous standard (14.05%). The method of the present invention may replace chemical-bath-deposited CdS with sputtered CdS:O and also replacing the high-temperature sputtered ZnTe:Cu back contact layer with co-evaporated and rapidly annealed ZnTe:Cu.

An aspect of the present invention is a method for preparing a back contact of a solar cell. The method includes providing a substrate, depositing at least one layer of a metal oxide to at least one surface of the substrate to produce a coated substrate, and depositing at least one layer of a metal sulfide to the at least one layer of the metal oxide surface of the coated substrate to produce a sulfide coated substrate. Then co-evaporating ZnTe:Cu on the sulfide coated substrate, and annealing the substrate by rapid thermal processing.

Another aspect of the invention is a method to fabricate a back contact. The method includes depositing at least one layer of a metal oxide coating onto a substrate to form a coated substrate. The metal oxide is applied to the substrate by chemical vapor deposition. At least one layer of a metal sulfide is deposited to the coated substrate to produce a sulfide coated substrate. The metal sulfide is applied to the coated substrate by a method selected from the group consisting of thermal evaporation, and reactive sputtering. An absorbant layer is deposited to the sulfide coated substrate to prepare an intermediate coated substrate. The absorbant layer is applied by a method by vapor transport deposition. The intermediate coated substrate is subjected to sublimation to produce a sublimated substrate. A buffer layer is deposited on the sublimated substrate to produce a buffer layer substrate. The buffer layer is deposited by thermal co-evaporation. A metalized layer is deposited on the buffer layer substrate to produce a device. The device is annealed by rapid thermal processing to produce the back contact.

Another aspect of the invention is a back contact. The back contact includes at least one metal oxide layer, at least one metal sulfide layer adjacent to the metal oxide layer, and at least one metal layer adjacent to the at least one metal sulfide layer. The material of the metal layer is CdTe. The back contact also includes at least one buffer layer adjacent to the metal layer. A material of the buffer layer is ZnTe:Cu. The back contact also includes at least one precious metal layer, wherein an open current voltage of the back contact is above about 830 V.

### BRIEF DESCRIPTION OF THE FIGURES

FIG. 1 illustrates a cross section of a photocurrent generated at the pn junction of a solar cell;

FIG. 2A illustrates different RTP treatments and the resulting efficiency;

FIG. 2B illustrates the current density as a function of voltage for as-deposited, over-heated and optimal RTP treatments;

FIG. 3 illustrates the quantum efficiency as a function of wavelength for different RTP treatments;

FIG. 4A illustrates the carrier density as a function of depletion width for two RTP treatments;

FIG. 4B illustrates a comparison of TRPL measurements;

FIG. 5 illustrates SIMS and APT data for different RTP treatments;

FIG. 6A illustrates TEM images of samples before APT processing, 2D images of the resulting elemental reconstruction and 1D volume averaged concentrations of the back contact region obtained from an as-deposited sample;

FIG. 6B illustrates TEM images of samples before APT processing, 2D images of the resulting elemental reconstruction and 1D volume averaged concentrations of the back contact region obtained from an optionally processed sample;

FIG. 6C illustrates TEM images of samples before APT processing, 2D images of the resulting elemental reconstruction and 1D volume averaged concentrations of the back contact region obtained from an overheated sample;

FIG. 7A illustrates postulated band diagrams of the back contact region for as deposited RTP samples; and

FIG. 7B illustrates postulated band diagrams of the back contact region for optimized RTP samples.

### DETAILED DESCRIPTION

The present invention relates electrical back contacts and methods to produce the back contacts using RTP. In some embodiments, layers of silver, ZnTe:Cu, CdTe, CdS:O, CD TO, and CD FTO may be applied to a glass substrate. The method may include a Br₂/CH₃OH etch, co-evaporating ZnTe:Cu at about 100° C., and exposing the substrate sequentially to about 30 cycles of RTP annealing.

### Method

An aspect of the invention is a method to fabricate a back contact. The method includes depositing at least one layer of a metal oxide to a substrate. The material of the metal oxide may be at least one of fluorine-doped tin oxide, or tin oxide, or the like. If multiple layers of the metal oxide are used, they may be the same or they may be different. The metal oxide coated substrate may then be coated with a metal sulfide.

In some embodiments, the metal oxide may be a transparent conductive oxide. In some embodiments, the metal oxide may have been previously applied to the substrate. The metal oxide may be applied to the substrate by chemical vapor deposition. The thickness of a layer of the metal oxide may be any suitable thickness. The metal oxide may cover at least about a portion of a surface of a substrate. The substrate may be glass, metal foils, or any other suitable substrate material. The substrate may be flexible. In some embodiments, the glass may be TEC-15 (available from Pilkington), an alkali free borosilicate glass, such as Corning 7059 glass (available from Corning).

The metal sulfide may be selected from the group consisting of CdS, CdS:O, other similar materials, and combinations thereof. The thickness of the metal sulfide layer may be between any suitable thickness. The total thickness of the metal sulfide may be between about 100 nm and about 250 nm. In some embodiments, the total thickness of the metal oxide layers may be about 100 nm, about 150 nm, or about 250 nm. The metal sulfide may be applied to the coated substrate by thermal evaporation, reactive sputtering, or other suitable deposition methods. The temperature of the thermal evaporation may be between about 125° C. and about 175° C., in some embodiments about 150° C.

An absorbant layer may be added to the metal sulfide coating. In some embodiments, the material of the absorbant layer may be CdTe, or other suitable materials. The absorbant layer may be applied to the metal sulfide coating by vapor transport deposition, sublimation, or other suitable deposition methods. Vapor transport deposition may occur at a temperature between about 425° C. to about 475° C., in some embodiments about 450° C. The coated substrate may be maintained at a temperature between about 575° C. to about 625° C., in some embodiments about 600° C. Each absorbant layer may be between about 2 μm and about 4 μm thick, in some embodiments about 3 μm.

The absorbant layer may be applied by sublimation. The gas may be formed from CdCl₂, or other suitable gases, or a combination of gases thereof. The sublimation may be a closed spaced sublimation. The temperature of the sublimation may be between about 375° C. to about 425° C., in some embodiments about 400° C. The exposure time of the sublimation may be between about 15 minutes to about 45 minutes, in some embodiments about 30 minutes. A gas may be used for the sublimation process. In some embodiments, the gas may be oxygen, nitrogen, similar gases, and combinations thereof. In some embodiments a 50-50% O₂/N₂ gas may be used. In some embodiments the device with a combination of layers may be subjected to sublimation at these parameters.

At least one buffer layer may be deposited on the absorbant layer. In some embodiments, the buffer layer may be ZnTe:Cu. The thickness of each of the buffer layer (ZnTe:Cu) may be between about 165 nm to about 200 nm, in some embodiments about 165 nm, about 175 nm, about 180 nm, about 190 nm, or about 200 nm. In some embodiments, the thickness of the ZnTe layer may be between 125 nm to about 175 nm, in some embodiments about 150 nm. The thickness of the copper layer may be between about 5 nm and about 20 nm. The buffer layer may be applied by co-evaporation of the ZnTe and Cu. In some embodiments, the substrate may remain unheated during the co-evaporation. The temperature of the thermal co-evaporation may be at least about 100° C., in some embodiments at about 100° C. in order to avoid moisture contamination. This temperature range is significantly lower than prior art methods which utilize high-temperature sputtering. One skilled in the art would understand that the copper concentration would be dependent upon the RTP temperature, and time used to make the remaining underlying layers, in particular the CdTe absorbant layer.

At least one metallization layer may be added to the buffer layer. In some embodiments, the metallization layer may include, but is not limited to, titanium, chromium, gold, silver, copper, nickel, palladium, and platinum, or combinations thereof.

The surface of the substrate may be processed prior to application of the metal oxide. In some embodiments, the surface may be etched in an approximate 0.5% (v/v) Br₂/CH₃OH solution for between about 5 seconds to about 15 seconds, in some embodiments about 10 seconds. Following the etching, the surface may be rinsed with an alcohol. The alcohol may any suitable alcohol, including but not limited to, ethanol, methanol, propanol, isopropanol, and combinations thereof.

After device fabrication, the device may be annealed by RTP by exposing the device for between about 15 seconds to about 45 seconds, in some embodiments about 30 seconds. The RTP treatments may occur in the presence of an inert gas, which may include but is not limited to, argon, nitrogen, helium, and combinations thereof. The temperature of the RTP treatment may between about 300° C. to about 340° C.

### Apparatus Properties

An aspect of the invention is a CdTe cell with an efficiency above about 14%. In some embodiments, the efficiency of the CdTe cell may be greater than about 16%. In some embodiments, the V_{OC} may be greater than about 830 V. In some embodiments, the V_{oc} may be greater than about 850V. In some embodiments, the V_{oc} may be between about 830V and about 860V. The FF may be between about 70% and about 75%. Furthermore, the Cu profile of the device may be optimal.

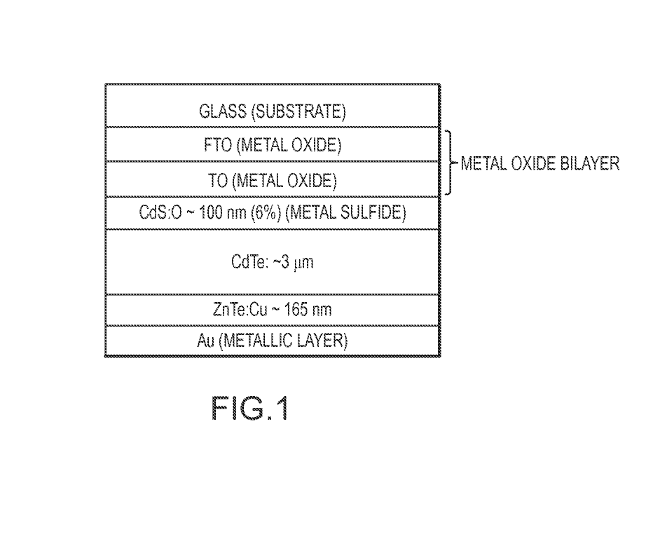

FIG. 1 illustrates front contact is transparent, and typically a transparent conductive oxide (TCO), such as a fluorinated tin oxide (FTO), cadmium stannate, for ITO. It is termed the front contact because light enters the cell through this contact. The back contact is adjacent to the CdTe and is an opaque metal such as gold, chromium, nickel or the like. There may be a buffer layer, such as ZnTe:Cu inserted between the CdTe and the metal contact. Alternative buffer layer materials include antimony telluride or a thin layer of copper. As used herein the term back contact means the ZnTe:Cu and the metallization layer (Au) combined).

### EXAMPLES

### Example 1

### Fabrication

The CdTe cells used in this experiment were fabricated using methods of the present invention. Throughout this example, comparisons are made among sets of three devices in which the fabrication steps through deposition of the back contact were identical, with the only parameter varied being the nature of the RTP treatment. “As-deposited” samples refer to devices that were contacted with a ZnTe:Cu:Au bilayer, but not subjected to RTP annealing. “Optimal” samples were subjected to a 30 seconds RTP treatment at an optimized setpoint temperature that was 300-340° C. depending on the specific superstrate employed. “Over-heated” samples received an additional 30 seconds RTP treatment at slightly elevated temperature. The samples employed the Corning 7059 front contact.

### Testing

The solar cell performance was measured under simulated AM1.5 radiation using a commercial tool that is calibrated using a certified silicon standard (PV Measurements). Quantum efficiency (QE) was measured on a custom system with a grating monochromator and lock-in amplifier detection. For these measurements no intentional white light bias is added to the mechanically chopped monochromatic light. Results are calibrated by comparison to a standard silicon solar cell previously measured at the National Renewable Energy Laboratory (NREL). Capacitance Voltage (CV) was measured on an Agilent HP4284A precision LCR meter controlled by Labview at 100 kHz and with a 10 mV AC signal. Time resolved photoluminescence (TRPL) measurements used to determine minority carrier lifetime were performed at NREL using 650 nm pulsed laser excitation. Dynamic SIMS was performed using an ION-TOF Model IV, and the copper density was quantified by normalizing the measured Cu/Te ratio to the copper content in the as-deposited sample which was quantified by APT. APT analyses were performed on a Cameca LEAP 4000X Si local electrode atom probe instrument using parameters optimized for quantitative evaluation of these materials. Additionally, transmission electron microscopy (TEM) images before and after APT analyses were acquired with a Philips CM200 TEM using a holder specifically designed for imaging APT specimens.

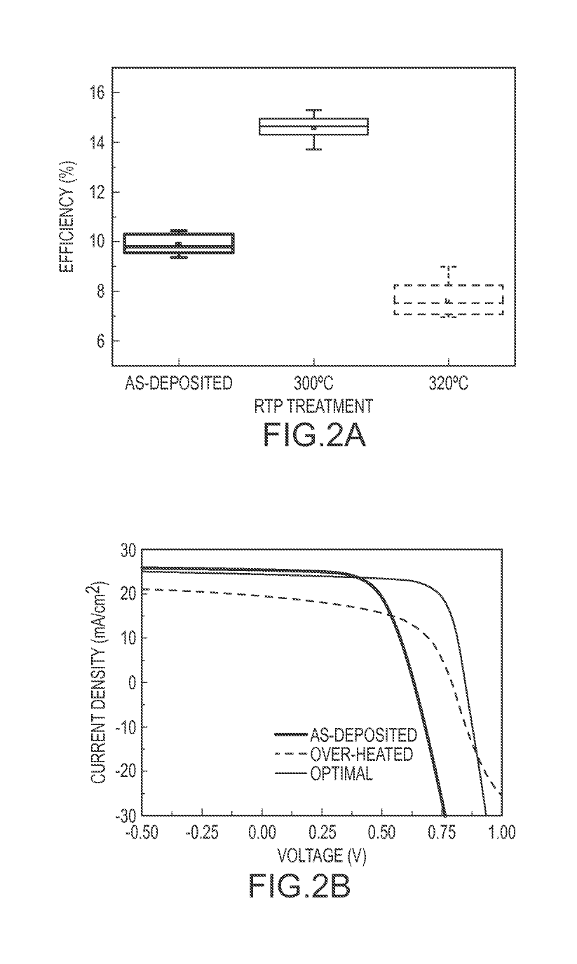

FIG. 2A illustrates box plots comparing the efficiency obtained from eight to ten devices in the as-deposited state (bold line), after an optimal RTP treatment (regular lines), and from an overheated sample (dashed line). Fifty percent of the measurements fall within the box, while the position of the error bars reflect the maximum and minimum obtained from each sample. FIG. 2B illustrates representative current-voltage curves from this set of devices (FIG. 2A) and the associated device parameters are summarized in Table 1.

TABLE 1

| Sample | V_{OC} (mV) | J_{SC} (mA/cm²) | FF (%) | Efficiency (%) |
|---|---|---|---|---|
| As-deposited | 636 | 25.4 | 62.2 | 10.0 |
| Optimal | 852 | 24.3 | 73.7 | 15.3 |
| Overheated | 793 | 19.4 | 54 | 8.3 |

For the samples, the optimal RTP treatment consisted of a single 30 s treatment at a setpoint temperature of 300° C. The overheated sample was exposed to an additional 30 second treatment at 320° C. Note that nominally identical results were observed for devices employing the TEC15/CdS front contact. The as-deposited device showed good current collection, but the efficiency was just 10% due to the low open circuit voltage of just 636 mV. After the optimal RTP treatment there were significant improvements in both V_{OC} (852 mV) and FF (73.7%) that are consistent with the elimination of back contact barriers. The J_{SC} value remains essentially unchanged, and thus the overall efficiency was elevated to 15.3%. After receiving the second 30 second RTP treatment the efficiency was greatly attenuated (8.9%), with losses in V_{OC}, FF, and J_{C}. While not wanting to be bound by theory, the significant decrease in J_{SC} could be attributed to the presence of excess Cu in the CdTe that form defects that serve as recombination centers. Another possibility is shunting, which is commonly observed when significant Cu has diffused to the CdS layer, thus degrading the quality of the heterojunction.

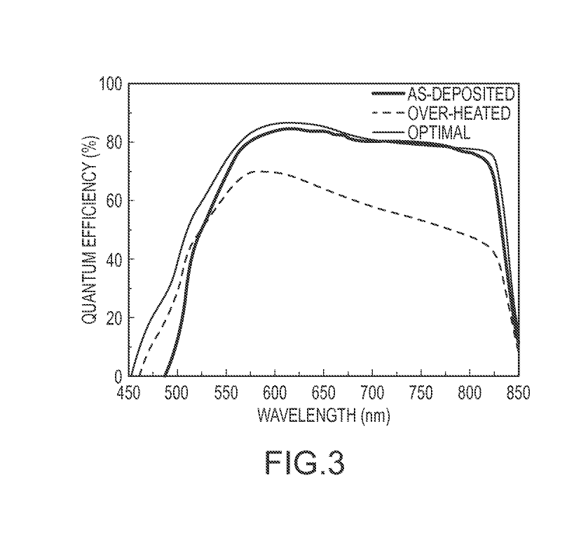

Measurements of quantum efficiency, carrier density and lifetime are consistent with the J-V behavior. FIG. 3 illustrates a comparison of the QE response obtained from devices prepared in the as-deposited, optimal, and overheated states. The QE of the as-deposited and optimally processed devices were quite similar as would be expected from their J_{SC} values, showing that the optimal RTP treatment does not significantly impact the properties of the front contact or the CdTe absorber. In contrast, excessive heating is deleterious to current collection throughout the visible spectrum. In particular, significant QE loss is observed in the red portion of the spectrum, behavior which has previously been correlated with copper content and ascribed to related defects that cause voltage-dependent collection.

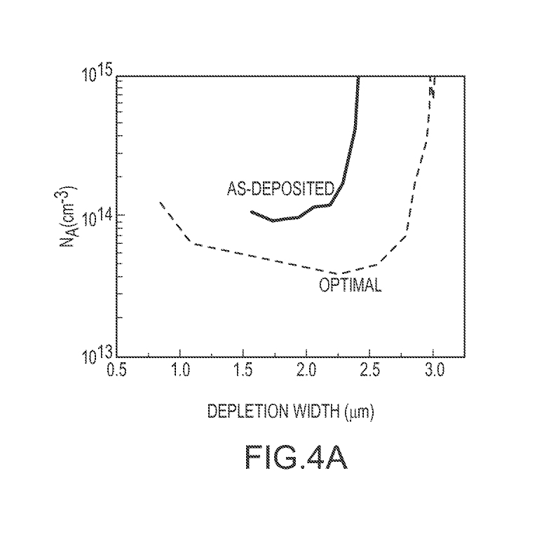

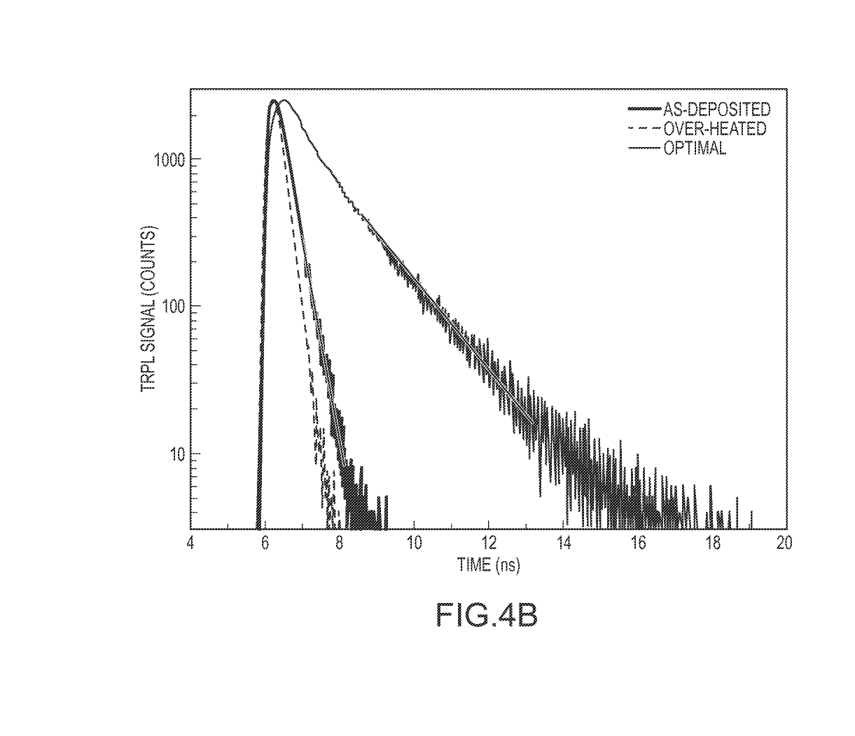

FIG. 4A illustrates the carrier density profile for the as-deposited and optimally processed samples. The overheated sample displayed very high leakage current, providing unreasonable results and as such was excluded from this comparison. Both of the remaining samples display U-shape profiles characteristic of CdTe/CdS solar cells. The carrier concentrations were estimated from the bases of these curves to avoid the complications that can occur at both forward and reverse bias. The results are somewhat surprising, in that the apparent acceptor density actually declined after optimal RTP treatment from about 10¹⁴ to 4×10¹³ cm⁻³. However, these changes are small, and suggest that the observed device improvements are not due to copper doping of the CdTe.

FIG. 4B illustrates a comparison of TRPL measurements which were used to extract minority carrier lifetimes (T) for these samples. After optimal RTP treatment, τ jumped by a factor of five from 0.3 ns in the as-deposited sample to 1.5 ns. With excessive heating τ declined to values less than the as-deposited case. Open circuit voltage has been strongly correlated with lifetime, although the underlying reasons for this relationship are not fully understood. For devices contacted with CuxTe it was observed that lifetimes declined with increasing copper, which was attributed to the formation of defects in the bulk or near the CdS/CdTe heterojunction that serve as recombination centers. In contrast, for devices contacted with ZnTe:Cu lifetimes increased to an optimal value that was a strong function of contacting temperature, not dissimilar from the behavior observed here. Recently it has been shown that 1 photon TRPL using excitation above the band gap may be more sensitive to surface than bulk recombination, particularly in thin film devices. The addition of buffer layers is expected to introduce interface defect states that can create dipole layers. The resulting fields would oppose the built-in field associated with the junction, and thus their removal by post-deposition processes such as RTP would increase the energy of collected carriers. An optimally formed ZnTe:Cu back contact will also have a large conduction band offset at the CdTeZnTe interface, creating an electron reflector that keep electrons from getting to the ZnTe metal interface. It is postulated that the large increase in τ and V_{OC} observed under optimal RTP conditions is due to modification or passivation of these interface states, and an associated reduction in recombination and barriers in the back contact region.

### Copper Migration

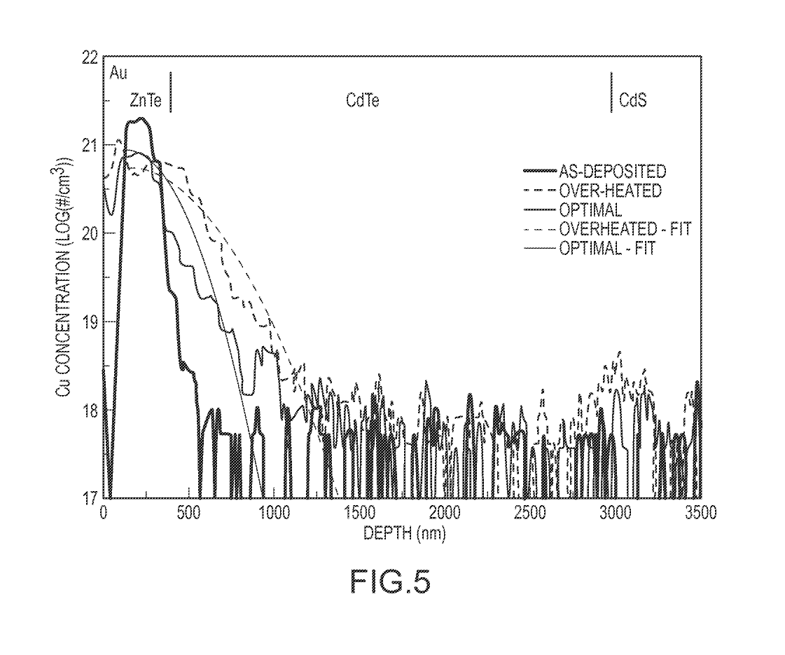

To better understand how copper migration may be influencing the results of Experiment 2, its distribution was measured using SIMS and APT using a set of TEC15/CdS based devices. The former provides an averaged 1D profile throughout the device structure, while APT was used to create 3D reconstructions of the structure and elemental distribution in the back contact region. FIG. 5 illustrates displays SIMS profiles confirming systematic variation in Cu diffusion into the CdTe layer as a result of RTP treatment. The as-deposited case illustrates that that copper is uniformly distributed through the ZnTe layer in a step profile as expected. Upon RTP treatment copper diffuses out of the ZnTe layer into both the CdTe absorber as well as into the gold contact (the first ˜150 nm of the depth profile). The latter is not surprising since copper and gold form completely miscible solid solutions. Also as expected, successive RTP treatments further deplete the ZnTe layer and increase the extent of copper diffusion into the device. For the optimal device Cu extends ˜1 μm into the CdTe before falling below the sensitivity limit of the instrument. The overheated sample displays higher Cu levels in the CdTe, and there is also some evidence of copper accumulation in the CdS layer, which would be consistent with the shunting behavior observed in those devices (FIG. 2(B)).

The smooth curves running through the data are Gaussian profiles that are the solutions to Fick's second law, approximating the initial Cu distribution as a delta function (Equation 1):

$$C ( x , t ) = \frac{{Q}_{r}}{\sqrt{π Dt}} exp ( \frac{- {x}^{2}}{4 Dt} ) \qquad ( 1 )$$

where the two adjustable parameters are the initial dose, QT, and a characteristic diffusion length \sqrt{Dt}. For both profiles the dose was fixed at QT=2×1016 cm−2 and the diffusion lengths were 0.13 and 0.21 μm for the optimal and overheated samples, respectively. These simple analytical solutions do a relatively good job of modeling the experimental profiles, and the parameters employed provide insight into the processes that are occurring. The total dose of copper provided in the as-deposited ZnTe:Cu layer was 1×10¹⁷ cm⁻². The lower value of 2×10¹⁶ cm⁻² that was found to best fit both diffusion profiles reflects the fact that a significant fraction, perhaps the majority, of copper provided in the buffer layer accumulates in the gold contact. Based on the RTP times employed one extracts diffusion coefficients that are on the order of 5×10⁻¹² cm²/s. These are surprisingly low values, and using the Arrhenius relationships for copper diffusion coefficients available in the literature it would suggest that the temperature of the sample was ˜150° C., significantly below the nominal RTP setpoint recorded by a thermocouple in contact with the susceptor. This contradicts evidence that suggest that during RTP processing the effective temperature of the CdTe layer is actually hotter than the value recorded by the thermocouple in contact with the AlN susceptor. At the short time scales involved radiation is selectively absorbed in the CdTe layer with the glass superstrate and AlN susceptor serving as heat sinks. Evidence in support of this hypothesis comes from observations that the RTP temperature setpoint must be reduced in order to achieve optimal performance when the thickness of the glass superstrate is reduced or when devices are intentionally placed in poor thermal contact with the susceptor. Assuming the CdTe layer is at temperature greater than or equal to that recorded by the thermocouple these results suggest that barriers at the ZnTe interface may inhibit Cu diffusion into the CdTe, accounting for the low effective diffusion coefficients observed. Such behavior would be consistent with recent reports of improved reliability with the use of ZnTe buffer layers.

### Atom Probe Tomography

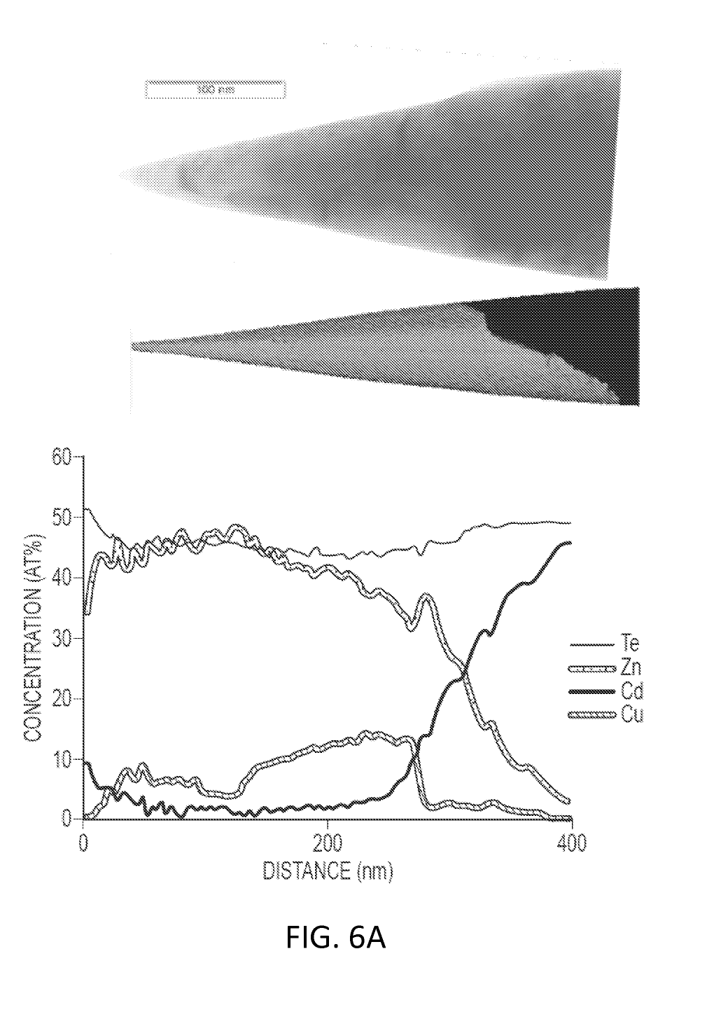

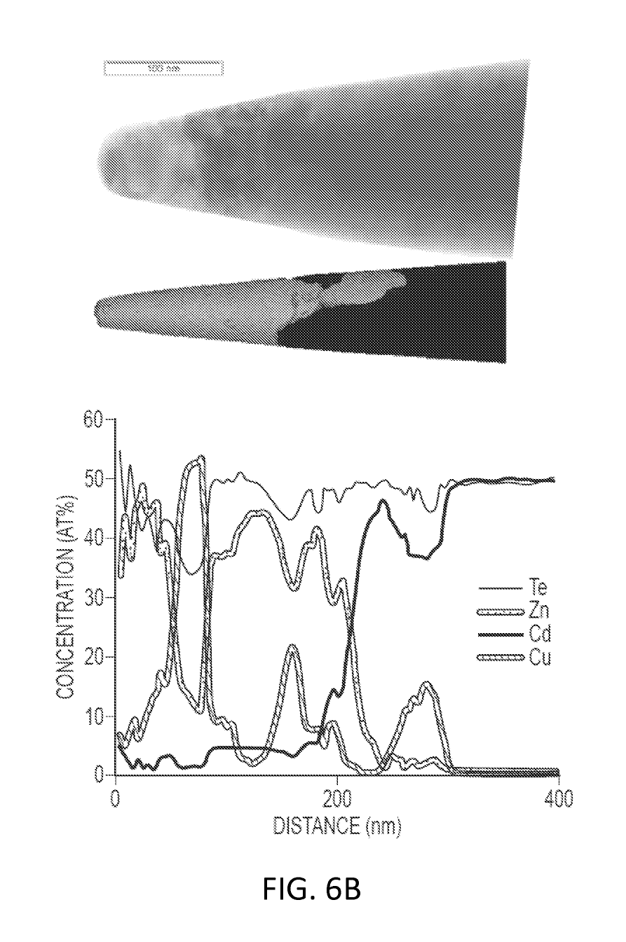

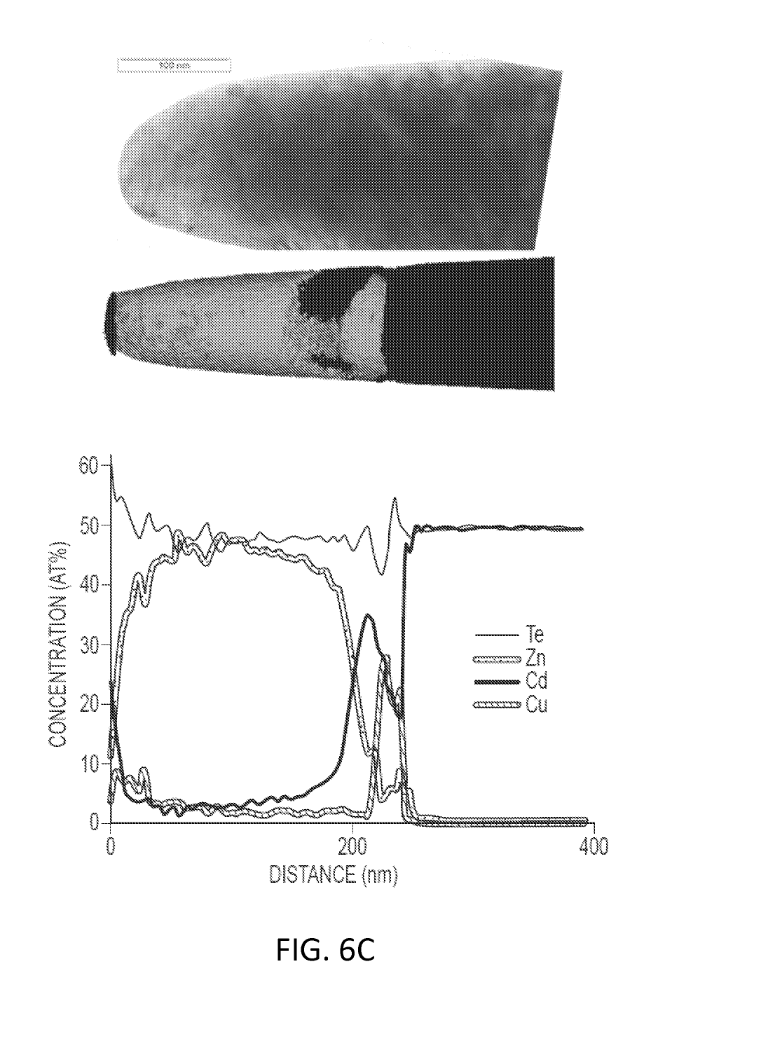

SIMS is very useful for providing an overview of the distribution throughout the device, but it provides profiles that are radially averaged due to the sputtering spot size. Atom probe tomography has been demonstrated to be a powerful tool for characterizing polycrystalline solar cells, and in particular its 3D capability has been recently deployed to characterize the segregation of impurities at the grain boundaries in CdTe devices. APT is applied to characterize the structure and composition of the three representative samples as illustrated in FIG. 6. Each of these figures includes a TEM image of the sample before APT, the resulting elemental reconstruction, and volume averaged 1D concentration profiles down the tip axis, which was approximately orthogonal to the layers. The original samples prepared by FIB contained a small portion of the Au contact (approximately 5-10 nm) at the apex, but this layer popped off during specimen turn on, likely due to the lower evaporation field for ZnTe than for Au. Therefore, zero on the x axis of the concentration profiles corresponds to the Au:ZnTe interface. In the APT images Cd is represented as black, Zn is grey, Cu is orange, and Te is excluded for clarity. Note that the images provided in FIG. 6 are just 2D representations of the full 3D reconstructions. Videos displaying the full 3D elemental distributions for these samples are provided in the supplementary information. A sharp ZnTe:CdTe interface is observed in all samples, demarked by the grey/black border. Significant heterogeneity in the copper distribution is observed in all samples as discussed below.

FIG. 6A displays the results for the as-deposited sample. During co-evaporation the intent was to deposit copper uniformly through-out the buffer layer sample, though in this sample higher levels are observed near the CdTe interface. The non-uniform profile is attributed to the challenges of the co-evaporation process. The evaporation rates of both constituents are controlled by independent power supplies and monitored by two QCMs. However the nominal evaporation rate of Cu is 0.5 Å/s, which is near the lower limit of the QCM's sensitivity, making control challenging. It is straightforward to control the total amount of copper deposited, but the variations observed in this APT sample are attributed to our ability to precisely control the local Cu evaporation rate. However, while the RTP process is sensitive to the total fraction of copper in the buffer layer, it is not significantly influenced by its initial distribution. Device results achieved with ZnTe:Cu bilayers were nominally identical to co-evaporated buffers. The volume-averaged copper content in the as-deposited buffer was about 9.8 at % (about 3.4 wt %), which is quite comparable to the nominal composition of ZnTe:Cu targets used in sputter deposition.

FIG. 6B illustrates the APT reconstruction of a sample processed with an optimal RTP treatment. In this case APT reveals considerable segregation of copper toward both the Au and CdTe interfaces. Comparison of FIGS. 5 and 6 highlights the power of APT for nanoscale analysis of these interfacial regions that are so critical to controlling the performance of thin film photovoltaic devices. The SIMS profile for these samples indicate that Cu is uniformly distributed throughout the ZnTe, where in reality it is highly localized with some individual regions exceeding 50 at %. These images suggest that copper redistribution within the ZnTe region is controlled primarily by thermo-dynamic parameters such as solubility and partition functions as opposed to Fickian diffusion. The high localized levels of Cu suggest the possibility of CuxTe formation, as the regions with elevated Cu content are well-correlated to displacement of Zn. This finding is perhaps not surprising given that the formation energy of Cu2Te is close to zero. So while CuxTe and ZnTe:Cu have been previously considered to be distinct buffer layers, these results suggest that they may share some notable similarities, at least when processed using RTP.

Finally, FIG. 6C illustrates the APT reconstruction of a sample that has been overheated during RTP treatment. It is remarkable that the application of just 30 seconds of additional RTP treatment beyond the optimized condition results in significant depletion of Cu from the ZnTe buffer layer. Characteristics of the CuxTe phase remain at the CdTe interface, but it is largely diminished at the Au interface. Significant Cd diffusion from the absorber layer is also observed. This is also seen in the optimal sample, but in the overheated sample the alloying process appears complete with a uniform density of ˜4 at % Cd throughout the ZnTe layer. In addition, significant Te and Cd accumulations at the Au interface are observed, which may be another contributing factor to the substantial decline in performance of the overheated sample.

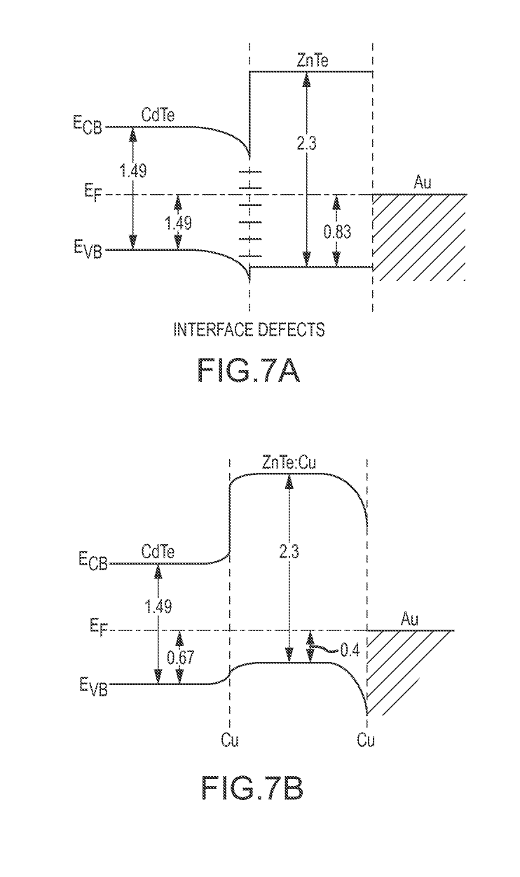

It is somewhat surprising that the heterogeneous structure produced under optimal RTP processing was correlated to such dramatic improvements in device performance. FIG. 7 illustrates proposed band diagrams of the back contact region illustrating the changes that occur in the optimized RTP process. FIG. 7A illustrates postulated band diagrams of the back contact region for as deposited RTP samples. FIG. 7B illustrates postulated band diagrams of the back contact region for optimized RTP samples. The electronic structure of the back contact region in the as-deposited state was based on the work of Späth et al., who constructed their band diagram of this heterojunction using ultraviolet photoelectron spectroscopy (UPS) measurements of the valence band maximum position relative to the Fermi level obtained from CdTe and after subsequent sputter deposition of ZnTe. While not wanting to be bound by theory, it is assumed that the Fermi level in the as-deposited ZnTe:Cu is similar to their value, because although Cu is present, it has not been thermally activated. In this structure there is a negligible valence band offset (˜0.1 eV) at the ZnTe:CdTe interface, but a significant Schottky barrier is present at the gold interface. In addition, since these layers are deposited at low temperature it is expected that there are significant densities of defects and trap states at the interface. Indeed it was suggested in the previous UPS work that defects must be present at this interface to ensure charge neutrality and explain why band bending only occurs in the CdTe layer. After optimal RTP treatment, two major changes are considered. First, the ZnTe:Cu layer becomes more p-type due to activation of Cu dopants, which shifts the valence band offset into a position that eliminates any barriers to hole transport at the ZnTe:CdTe interface. Second, it is postulated that the Cu migration to the interfaces observed by APT is critical for passivation of defect states, which allows band bending to occur on both sides of the ZnTe:CdTe interface. Note that a Schottky junction remains at the gold interface after RTP treatment, but the activation of dopants creates an efficient tunnel junction for charge transfer into the Au metallization layer. Finally this structure presents a formidable barrier to electron transport, which should minimize recombination in the back contact region. Rapid thermal processing is critical to enable the benefits shown in this work. The staggering changes that occur in the ZnTe buffer region after 30 seconds RTP treatments suggest that its structure is determined by thermodynamic quantities such as solubility and stability of the relevant phases. It is highly unlikely that the unique non-equilibrium structures observed in this work that are correlated with high performance could be achieved through conventional thermal processing. Decoupling buffer deposition and activation, combined with the precise control imparted by RTP, are identified as the key enablers. Finally, the low thermal budgets employed suggest that this process should be readily adapted to other systems. This attribute was recently demonstrated when the back contact procedure described here was applied to devices fabricated by the National Renewable Energy Laboratory based on about 100 μm flexible glass superstrates. Application of the RTP back contact contributed to elevating the certified efficiency of devices fabricated on this platform from 14% to >16%.

The foregoing description of the present invention has been presented for purposes of illustration and description. Furthermore, the description is not intended to limit the invention to the form disclosed herein. Consequently, variations and modifications commensurate with the above teachings, and the skill or knowledge of the relevant art, are within the scope of the present invention. The embodiment described hereinabove is further intended to explain the best mode known for practicing the invention and to enable others skilled in the art to utilize the invention in such, or other, embodiments and with various modifications required by the particular applications or uses of the present invention. It is intended that the appended claims be construed to include alternative embodiments to the extent permitted by the prior art.

1. A method for preparing a back contact of a solar cell, comprising:
providing a substrate;
depositing at least one layer of a metal oxide to at least one surface of the substrate to produce a coated substrate;
depositing at least one layer of a metal sulfide to the at least one layer of the metal oxide surface of the coated substrate to produce a sulfide coated substrate;
co-evaporating ZnTe:Cu on the sulfide coated substrate; and
annealing the substrate by rapid thermal processing.

2. The method of claim 1, wherein a material for the substrate is selected from the group consisting of glass, and metal foil.

3. The method of claim 1, wherein a material of the at least one layer of the metal oxide is at least one of fluorine doped tin oxide, and tin oxide.

4. The method of claim 1, wherein a material of the at least one layer of the metal sulfide is at least one of CdS, CdS:O.

5. The method of claim 1, wherein the annealing occurs in about 30 cycles.

6. The method of claim 1, wherein the annealing occurs in between about 20 and about 40 cycles.

7. The method of claim 1, wherein the co-evaporation occurs at a temperature between about 75° C. and about 125° C.

8. The method of claim 1, wherein the co-evaporation occurs at a temperature of about 100° C.

9. The method of claim 1, wherein the annealing occurs in less than about one minute.

10. The method of claim 1, wherein the annealing occurs in between about 30 seconds and about 2 minutes.

11. The method of claim 1, wherein the back contact is for use in a solar cell.

12. The method of claim 1, further comprising etching the substrate with a Br₂/CH₃OH mixture.

13. A method to fabricate a back contact, comprising:
depositing at least one layer of a metal oxide coating onto a substrate to form a coated substrate, wherein the metal oxide is applied to the substrate by chemical vapor deposition;
depositing at least one layer of a metal sulfide to the coated substrate to produce a sulfide coated substrate, wherein the metal sulfide is applied to the coated substrate by a method selected from the group consisting of thermal evaporation, and reactive sputtering;
depositing an absorbant layer to the sulfide coated substrate to prepare an intermediate coated substrate, wherein the absorbant layer is applied by vapor transport deposition;
subjecting the intermediate coated substrate to sublimation to produce a sublimated substrate;
depositing a buffer layer on the sublimated substrate to produce a buffer layer substrate, wherein the buffer layer is deposited by thermal co-evaporation;
depositing a metalized layer on the buffer layer substrate to produce a device; and
annealing the device by rapid thermal processing to produce the back contact.

14. The method of claim 13, wherein a material for the substrate is selected from the group consisting of glass, and metal foil.

15. The method of claim 13, wherein a material of the at least one layer of the metal oxide is at least one of fluorine doped tin oxide, and tin oxide.

16. The method of claim 13, wherein a material of the at least one layer of the metal sulfide is at least one of CdS, and CdS:O.

17. The method of claim 13, wherein a material of the at least one absorbant layer is CdTe.

18. The method of claim 13, wherein the rapid thermal processing occurs at a temperature between about 300° C. to about 340° C.

19. A back contact, comprising:
a substrate;
at least one metal oxide layer on the substrate;
at least one metal sulfide layer adjacent to the metal oxide layer;
at least one metal layer adjacent to the at least one metal sulfide layer, wherein a material of the metal layer is CdTe;
at least one buffer layer adjacent to the at least one metal layer, wherein a material of the at least one buffer layer is ZnTe:Cu; and
at least one precious metal layer, wherein an open current voltage of the back contact is above about 830 V.

20. The back contact of claim 19, wherein the open current voltage of the back contact is above about 850 V.
